(19) United States
(12) Patent Application Publication
(10) Pub. No.: US 2026/0067596 A1
(43) Pub. Date: Mar. 5, 2026

(54) DEPTH IMAGE SENSOR COMPRISING A MEANS FOR RESETTING THE PHOTOSENSITIVE REGION

(71) Applicant: COMMISSARIAT A L'ENERGIE ATOMIQUE ET AUX ENERGIES ALTERNATIVES, Paris (FR)

(72) Inventors: Olivier SAXOD, Grenoble Cedex (FR); Gaëlle PALMIGIANI, Grenoble Cedex (FR)

(21) Appl. No.: 19/318,591

(22) Filed: Sep. 4, 2025

(30) Foreign Application Priority Data
Sep. 5, 2024 (FR) FR2409422

(51) Int. Cl. H04N 25/78; H04N 25/705; H10F 39/00

(52) U.S. Cl. CPC H04N 25/78; H04N 25/705; H10F 39/8033; H10F 39/80373; H10F 39/807

(57) ABSTRACT

The invention relates to a depth image sensor. Each pixel of the sensor comprises first and second sense nodes and a collection zone vertically aligned with a photosensitive region formed in a substrate; first and second transfer transistors respectively comprising first and second vertical gates and first and second channels; a multi-gate initialization transistor of the photosensitive region, comprising a collection channel controllable by the first and second vertical gates. The channels of the transistors extend between, on one side, the photosensitive region and, on the other, the sense nodes and the collection zone. The readout circuit is configured to apply first and second electrical signals respectively to the first and second vertical gates so as to alternately turn on each of the first channel, the second channel and the collection channel passing, independently of the two other channels.

### TECHNICAL FIELD

The field of the invention is that of depth image sensors operating on an indirect time-of-flight measurement principle.

### PRIOR ART

Depth image sensors make it possible to obtain an image in relief of a scene. Such sensors include depth image sensors based on an indirect time-of-flight measurement principle, generally referred to as iToF (Indirect Time of Flight) image sensors. Such a depth image sensor generally comprises a depth pixel array. It is associated with a light source, for example a laser, for illuminating the scene. The light source emits a light signal that is periodic in amplitude, often sinusoidal. A pixel, or a group of contiguous pixels corresponding to a point of the image, samples the periodic signal received after reflection on the scene. The sensor comprises processing means for determining a phase shift between the periodic signals emitted and received, and converting the phase shift into a distance separating the image sensor from the point of the scene combined with the point of the image.

It is commonly accepted that at least three samples over a period of the periodic signal are required to perform a distance measurement. It is preferable to use four samples. A sample is an integration of the periodic signal received by a pixel for one or more time periods, each equal to a fraction of the period of the periodic signal, the time periods being spaced apart by a period of the periodic signal. Preferably, the fraction of the period of the periodic signal is the same for all the samples, for example equal to the reciprocal of the number of samples. Generally, the integration time periods of separate samples do not overlap.

A depth pixel comprises a photosensitive region configured to convert the photons from the received light signal into electrical charges, a first transfer transistor and a sense node. The transfer gate makes it possible to transfer the electrical charges from the photosensitive region to the sense node during the time periods corresponding to a sample. A sense node is a region of the depth pixel within which photogenerated charges are collected before being read out by a readout circuit.

The depth pixel generally further comprises a blind region designated for resetting the photosensitive region before each sampling phase. It contains an initialization transistor and a collection zone. The initialization transistor allows a discharge of the electrical charges from the photosensitive region to the collection zone via its channel. Document U.S. Pat. No. 10,162,048 relates to an iTOF image sensor comprising a pixel initialization transistor. Document FR3065320 relates to a more compact solution because the initialization transistor has a vertical gate. However, it appears to be necessary to reduce the volume occupied by the region designated for resetting the photosensitive region further.

Document U.S. Pat. No. 11,581,345 relates to an alternative solution to the initialization transistor, particularly attractive for its compactness. Each pixel comprises a vertical electrode isolated from the photosensitive region by a dielectric layer comprising charge traps at its interface with the photosensitive region. At the time of initialization of the photosensitive region, the vertical electrode is biased by a pulse train of a duration between 10 ns and 2 ms to generate an alternation of inversion and accumulation states in the photosensitive region, such that photogenerated charges in the photosensitive region are recombined in the charge traps.

However, it appears that resetting the photosensitive region is less effective with this solution than with an initialization transistor. Furthermore, it would be interesting to remove the interconnections specifically designated for the initialization of the photosensitive region.

### DISCLOSURE OF THE INVENTION

The aim of the invention is that of at least partially remedying the drawbacks of the prior art, and more particularly providing a depth image sensor comprising a plurality of pixels, each comprising a photosensitive region and a means for initializing the photosensitive region that is more compact than those of the devices of the prior art.

For this purpose, the subject matter of the invention is a depth image sensor comprising a readout circuit and a plurality of pixels formed in and on a substrate of the sensor. Each pixel comprises a photosensitive region formed in the substrate and configured to convert photons into electrical charges; a first sense node, a second sense node, and a collection zone vertically aligned with the photosensitive region and doped with a first conductivity type; a first transfer transistor comprising a first vertical gate and a first channel controllable by the first vertical gate; a second transfer transistor comprising a second vertical gate and a second channel controllable by the second vertical gate; a multi-gate initialization transistor of the photosensitive region, comprising the first and second vertical gates and a collection channel controllable by the first and second vertical gates. Each pixel is such that the first channel, the second channel, and the collection channel extend in the substrate between the photosensitive region and, respectively, the first sense node, the second sense node and the collection zone. The readout circuit is configured to apply a first electrical signal to the first vertical gate and a second electrical signal to the second vertical gate so as to alternately turn on each of the first channel, the second channel and the collection channel, independently of the two other channels.

Some preferred, yet non-limiting, aspects of this sensor are as follows.

The collection zone can extend vertically in the substrate to a greater depth than the first and second sense nodes.

Each pixel can further comprise a peripheral isolation trench which can extend vertically in the substrate from an upper face of the substrate and which can laterally delimit the photosensitive region.

The sensor can further comprise a doped well of a second conductivity type opposite the first conductivity type. The well can be in contact with the peripheral isolation trench and can be flush with the upper face of the substrate.

The peripheral isolation trench can comprise a vertical electrode made of a doped semiconductor material of the second conductivity type.

The first and second vertical gates can comprise respective main portions facing each other, symmetrical to each other relative to a vertical axis of symmetry passing through the center of the pixel and wherein the collection zone can extend from one main portion to the other.

The first and second vertical gates can each have a U-shape when viewed from above. The first sense node and the second sense node can each extend between two opposite branches of the U formed by, respectively, the first vertical gate and the second vertical gate.

The readout circuit can comprise an initialization contact. The pixel can further comprise a peripheral contact zone of the first conductivity type, which can extend the collection zone in a peripheral region of the pixel on which the initialization contact rests.

The readout circuit can be configured to switch in opposite phase, the first electrical signal and the second electrical signal between a first value and a second value so as to alternately turn on the first channel and the second channel during a sampling phase, while keeping the collection channel off.

The readout circuit can be configured to assign a third value to the first electrical signal and the second electrical signal so as to turn on the collection channel during an initialization phase of the photosensitive region preceding the sampling phase.

The plurality of pixels can be arranged in an array. The readout circuit can be configured to assign an electrical potential equal to an intermediate value to the first and second vertical gates so as to prevent a transfer of photogenerated electrical charges in the photosensitive region to the first and second sense nodes during an array readout phase, the intermediate value being different from the third value.

### BRIEF DESCRIPTION OF THE DRAWINGS

Other aspects, aims, advantages and features of the invention will become more apparent upon reading the following detailed description of preferred embodiments thereof, provided as a non-limiting example, and made with reference to the appended drawings wherein:

FIG. 1A is a schematic top view of a first embodiment of a depth image sensor;

FIG. 1B is an example of dopant atom mapping viewed in the sectional plane A-A of FIG. 1A;

FIG. 1C is a schematic view of the first embodiment along the cross-section A-A of FIG. 1A;

FIG. 2A is a schematic top view of a variant of the first embodiment of a depth image sensor;

FIG. 2B is an example of dopant atom mapping viewed in the sectional plane A-A of FIG. 2A;

FIG. 2C is the example of dopant atom mapping viewed in the sectional plane B-B of FIG. 2A;

FIG. 3A is an electrical diagram representative of the first embodiment and its variant;

FIG. 3B is an example of a timing diagram implemented by the first embodiment or its variant, when they are in operation;

FIG. 4A is an example of electrical potential mapping in sectional planes of the first embodiment and its variant, for a particular bias state;

FIG. 4B is an example of electrical potential mapping in sectional planes of the first embodiment and its variant, during a sampling phase;

FIG. 4C is an example of electrical potential mapping in sectional planes of the first embodiment and its variant, during a readout phase of the plurality of pixels or during an initialization phase;

FIGS. 5A and 5B are curves giving the value of the electrical potential of FIG. 4C, along particular horizontal segments;

FIGS. 6A, 6B, 6C, 6D, 6E, 6F and 6G are schematic top views of other embodiments according to the invention.

### DETAILED DISCLOSURE OF SPECIFIC EMBODIMENTS

In the figures and in the following description, the same references represent identical or similar elements. In addition, the different elements are not plotted to scale so as to favor clarity of the figures. Moreover, the different embodiments and variants are not mutually exclusive and could be combined. Unless stated otherwise, the terms “substantially”, “about”, “in the range of” mean within a 10% margin, and preferably within a 5% margin. Moreover, the terms “between . . . and . . . ” and equivalents mean that the bounds are included, unless stated otherwise.

The invention relates to a depth image sensor comprising a readout circuit and a plurality of pixels formed in and on a substrate of the image sensor. Each pixel comprises a photosensitive region, a means for initializing the photosensitive region, at least two sense nodes, and a transfer gate for each sense node capable of transferring photogenerated electrical charges in the photosensitive region to a corresponding sense node.

In the sensor of the invention, the means for initializing the photosensitive region is a multi-gate initialization transistor, the gates of which are the transfer gates. Applying a non-zero electrical potential to all transfer gates prioritizes the transfer of electrical charges from the photosensitive region to a drain of the initialization transistor, hereinafter called the collection zone. The collection zone is a region of the pixel distinct from the sense nodes. Thus, it is possible to initialize the photosensitive region of the pixel without additional gates or interconnections, in addition to those required for reading the samples.

In the description, a transfer of charges along a channel, or from one region to another, is said to be priority, if at least 90% of the electrical charges transferred are transferred by this channel, or from the region to the other. Where applicable, the proportion is preferably greater than or equal to 95%, or greater than or equal to 97%, or even greater than or equal to 99%.

When a first channel of a transistor is on independently of another channel or other transistor channels, the transfer of charges by the first channel is priority.

Particular embodiments will be described relating to a depth image sensor configured for a voltage reading. However, these embodiments can be adapted to other optoelectronic devices.

Each embodiment described hereinafter adopts a particular combination of conductivities associated with the doped zones, it being understood that the combination can be inverted without departing from the scope of the invention. Thus, for a particular embodiment, all P-doped zones can be N-doped and all N-doped zones can be P-doped, provided that the conductivity type of all of the doped zones is changed.

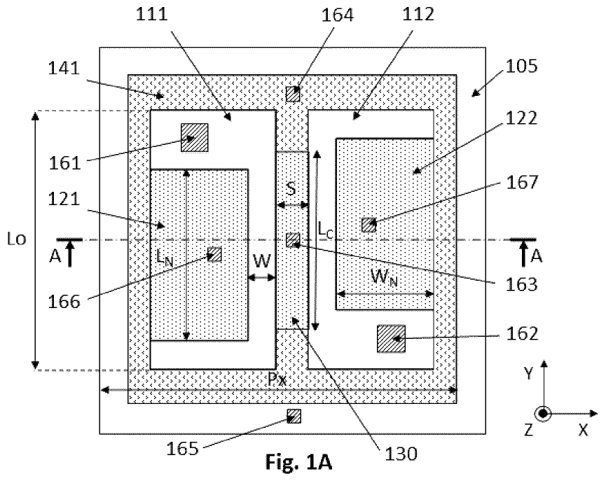

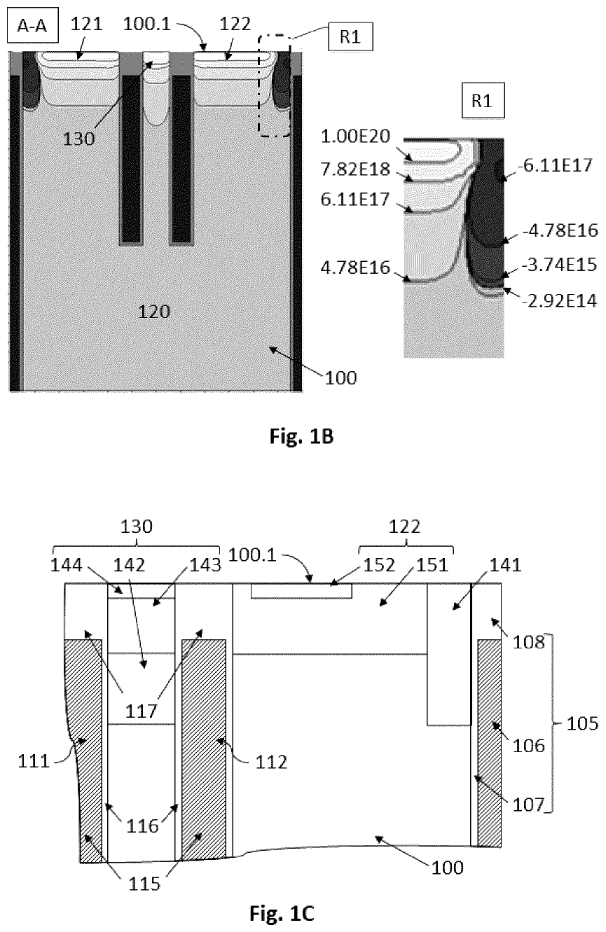

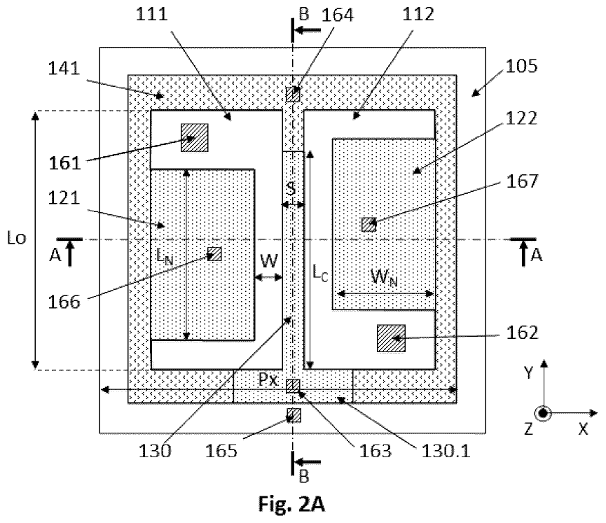

A first embodiment of an image sensor according to the invention will now be described in relation to FIGS. 1A, 1B and 1C. FIGS. 1A and 1C are schematic top and sectional views, respectively. The sectional plane of FIG. 1C is represented by a dash-dotted line in FIG. 1A. FIG. 1B shows a mapping of the concentration of dopant elements in the sectional plane of FIG. 1C, obtained by simulation.

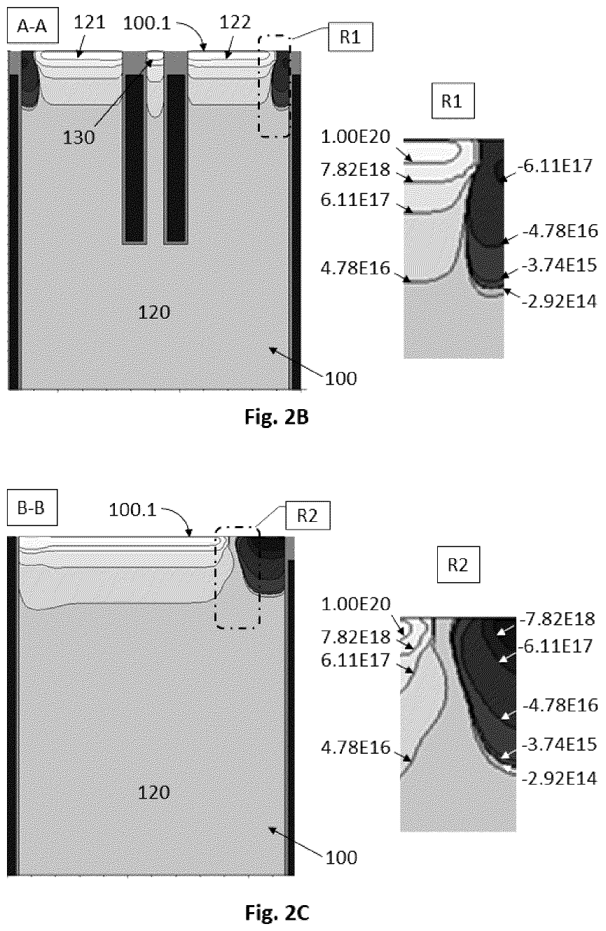

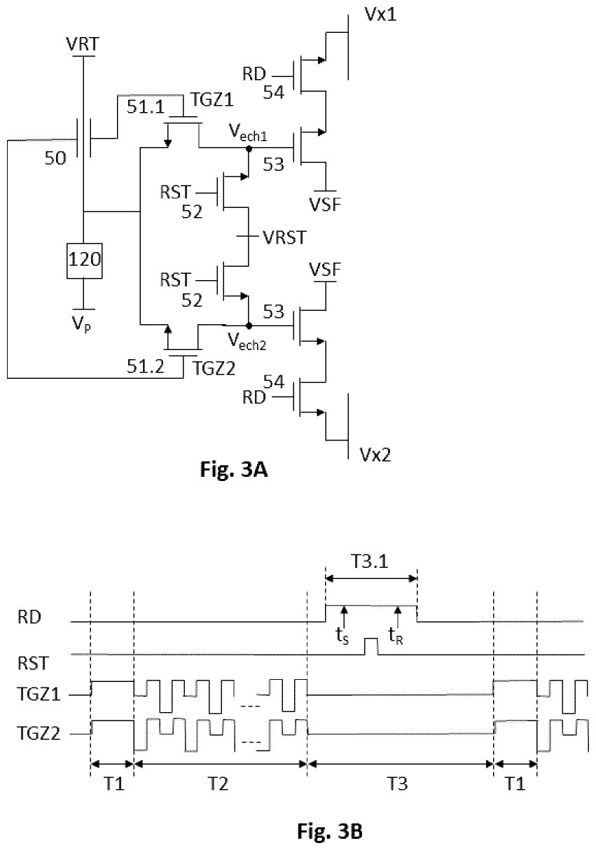

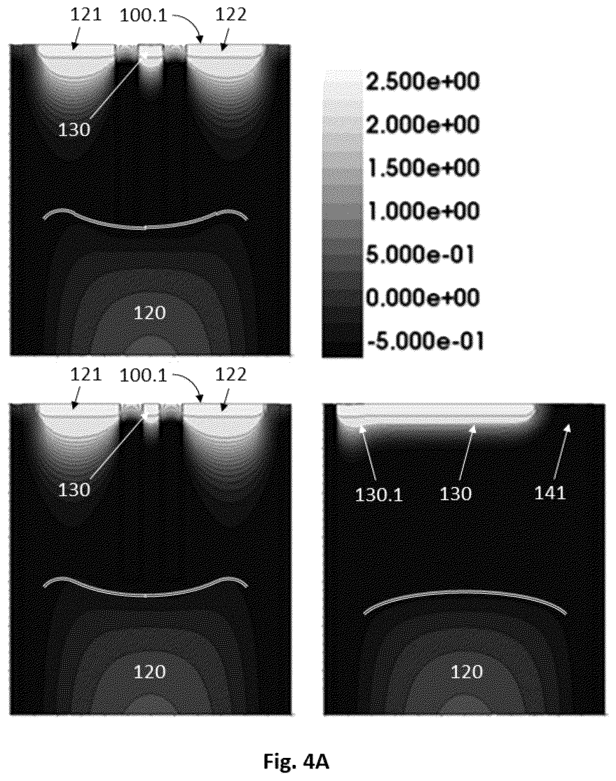

The grayscale mappings in FIGS. 1B, 2B, 2C, 4A, 4B and 4C are simulation results obtained with technology computer-aided design (TCAD) software. To the right of FIGS. 1B, 2B and 2C, the numerical values of concentrations of dopant atoms per cm³ corresponding to scale lines appearing within regions marked by borders in dash-dotted lines, on the left part of these figures, have been given. A negative value corresponds to a P-type doping, a positive value to an N-type doping. Although a grayscale is assigned to the dielectric parts of the pixel, it is not representative of a concentration of dopant atoms.

The first embodiment comprises a readout circuit and a plurality of pixels formed in and on a substrate 100. In FIGS. 1A to 1C, only one pixel has been shown. In order not to overload the diagrams, some elements have been omitted, such as the interconnection lines, for example. To improve readability, only an upper portion of the substrate 100 is shown in the sectional views. In the schematic views, the elements are represented by simple geometric shapes. These are reproduced on the device produced excluding manufacturing errors, such as alignment, dimensional errors or corner roundings caused by a lack of resolution.

The substrate 100 comprises an upper face 100.1 and a lower face opposite the upper face 100.1. The lower and upper faces 100.1 are substantially planar and parallel to each other. The pixel comprises a photosensitive region 120, a first sense node 121, a second sense node 122, a collection zone 130, a P-well 141, a first vertical gate 111 and a second vertical gate 112. The first and second sense nodes 121, 122, the first and second vertical gates 111, 112, the collection zone 130 and the P-well 141 are flush with the upper face 100.1.

Herein and for the remainder of the description, an orthogonal three-dimensional direct reference frame (X, Y, Z) is defined, wherein the axes X and Y form a plane parallel to the upper face 100.1 of the substrate 100, the axis X being oriented parallel to the sectional plane A-A, and wherein the axis Z is oriented substantially orthogonally to the upper face 100.1 of the substrate 100, from the lower face to the upper face 100.1. In the following description, the terms “vertical” and “vertically” are defined as relating to an orientation substantially parallel to the axis Z, and the terms “horizontal” and “horizontally” as relating to an orientation substantially parallel to the plane (X, Y). Furthermore, the terms “lower” and “upper” are defined as relating to an increasing position when moving in the direction +Z. The term “lateral” refers to an orientation substantially parallel to the axis Z. A top view is a view in the direction −Z.

As is known per se in the technical field, a vertical gate comprises a gate electrode extending vertically in the substrate over a depth strictly greater than its horizontal dimensions. For example, this depth can be at least 2 times greater, 5 times, or even 10 times greater than one of its horizontal dimensions. Such a vertical gate further comprises a gate oxide coating the gate electrode so as to electrically isolate it from the substrate. A vertical gate controls a channel extending in depth in the substrate along the gate oxide.

The substrate 100 is made of a semiconductor material. Here it is made of crystalline silicon. For example, it consists of a silicon wafer or part of a silicon wafer. It can comprise one or more epitaxial crystalline silicon layers, and also one or more passivation layers.

In this example, the pixel comprises a peripheral isolation trench 105 extending vertically in the substrate 100 from the upper face 100.1. Preferably, the peripheral isolation trench 105 extends through of the substrate 100. Here, the peripheral isolation trench 105 is a capacitive isolation trench. It delimits the photosensitive region 120 in a horizontal plane. Viewed from above, it surrounds the photosensitive region 120 on all sides and has a closed contour, here of substantially square shape, with sides parallel to the axis X or the axis Y. In the plane of the upper face 100.1, the distance Px separating an outer edge on one side of the square from an inner edge on the opposite side of the square defines a pixel size. In this example, the pixel size Px is equal to 1.2 μm. It can be less than or equal to 1.2 μm, or even less than or equal to 1 μm.

The peripheral isolation trench 105 comprises a transverse inner wall, located on the side of the center of the pixel. It comprises a vertical electrode 106 made of an electrically conductive material. The vertical electrode 106 can be made of a metal, a metal alloy or a doped semiconductor material. It is here made of P-doped polycrystalline silicon. It extends vertically facing the photosensitive region 120, preferably facing all of the photosensitive region 120.

The peripheral isolation trench 105 further comprises an interposed dielectric layer 107 coating the vertical electrode 106, on all of the inner wall of the peripheral isolation trench 105. The interposed dielectric layer 107 is made of any dielectric material. Here it is made of silicon oxide.

The peripheral isolation trench 105 has, for example, a horizontal width of between 20 nm and 300 nm, here equal to 100 nm. It has a vertical height of between 1 μm and 20 μm, preferably equal to the thickness of the substrate 100.

In this example, the peripheral isolation trench 105 comprises, on the side of the upper face 100.1 of the substrate 100, an optional isolating region 108 resting on an upper end of the vertical electrode 106, so as to be in physical contact therewith. The isolating region 108 is made of an electrically insulating material. It can be made of an identical dielectric material to the interposed dielectric layer 107. Here it is made of silicon oxide.

When the plurality of pixels is arranged in an array in rows and columns, the rows and columns preferably extend, respectively, along the axes X and Y. Where applicable, two adjacent pixels of the array can share a part of their peripheral isolation trenches 105. Thus, the peripheral isolation trenches 105 of all of the pixels can together form an orthogonal mesh when viewed from above, for example square meshes of sides parallel to the axes X and Y.

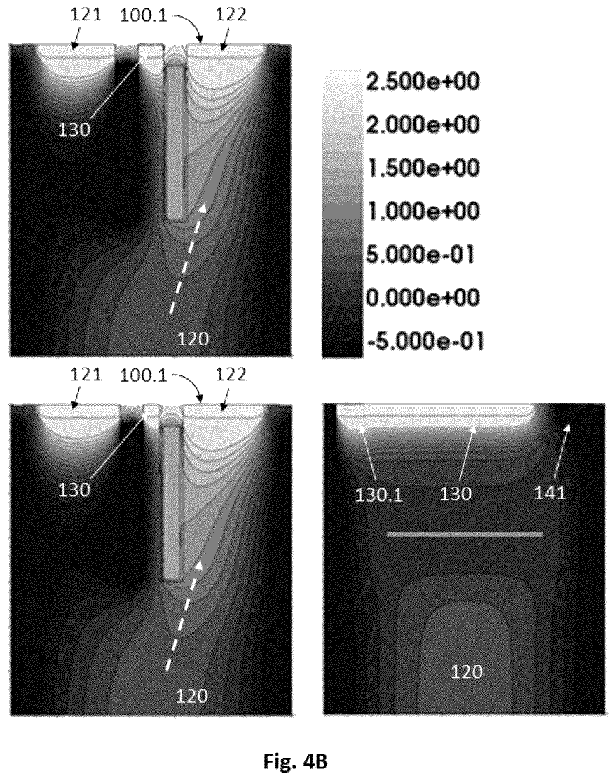

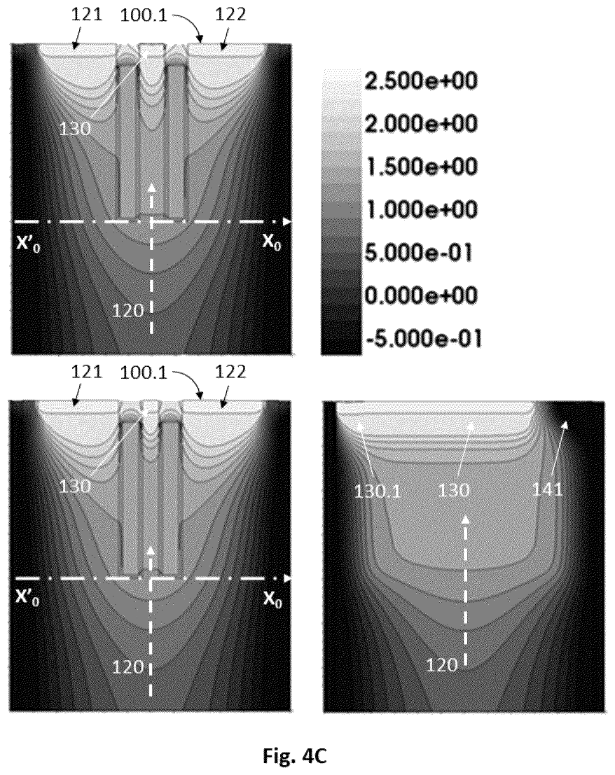

The pixel further comprises a first transfer transistor 51.1 and a second transfer transistor 51.2 (identified in the electrical diagram of FIG. 3A). The first transfer transistor 51.1 comprises the first vertical gate 111 and a first channel controllable by the first vertical gate 111. Similarly, the second transfer transistor 51.2 comprises the second vertical gate 112 and a second channel controllable by the second vertical gate 112. The first and second sense nodes 121, 122 form a drain of the first transfer transistor 51.1 and the second transfer transistor 51.2, respectively.

In this example, so as to simplify the design of the pixel, the first and second vertical gates 111, 112 are identical, without this being an essential feature of the invention. Here, they are arranged in the pixel so as to be symmetrical to each other relative to an axis of symmetry parallel to the axis Z and perpendicular to the upper face 100.1 of the substrate 100. Here, the axis of symmetry passes through the center of the pixel. Thus, only the first vertical gate 111 is described in detail hereinafter.

The first vertical gate 111 extends vertically in the substrate 100, in part facing the first channel, from the upper face 100.1, to a depth strictly less than the height of the peripheral isolation trench 105. Similarly, the second vertical gate 112 extends vertically in the substrate 100, partially facing the second channel, from the upper face 100.1, over a depth equal to the depth of the first vertical gate 111.

The first vertical gate 111 has a U-shape when viewed from above. It comprises a main portion forming the base of the U, extending parallel to the plane (Y, Z), and also a first branch and a second branch of the U extending parallel to the plane (X, Z). In this example, the main portion and the first branch have horizontal widths substantially equal to a value W. The second branch here has a horizontal width strictly greater than W. The horizontal width of the second branch is for example sufficient to ensure that a first gate contact 161 of the readout circuit rests entirely on the second branch despite manufacturing uncertainties.

The first vertical gate 111 comprises a gate electrode 115, an isolating layer 116 and an optional isolating region 117. It has a similar structure to the peripheral isolation trench 105. The gate electrode 115 is made of an electrically conductive material, for example of metal, metal alloy or doped semiconductor. It can be made of an identical material to that of the vertical electrode 106. Here it is made of P-doped polycrystalline silicon.

The isolating layer 116 entirely coats all of the lateral faces and the lower face of the gate electrode 115. It is made of an electrically insulating material, for example of any type of dielectric material. Here it is made of silicon oxide.

The isolating region 117 rests on an upper end of the gate electrode 115, so as to be in physical contact therewith. It is made of an electrically insulating material, advantageously of the same material as the isolating region 108. It can be made of an identical dielectric material to the isolating layer 116. Here it is made of silicon oxide. When the isolating regions 108 and 117 are made of the same material and extend from the upper face 100.1 over the same depth, as shown here, they can be produced simultaneously.

For example, the first and second vertical gates 111, 112 have a horizontal width W of between 20 nm and 300 nm, here equal to 100 nm. They have a vertical height of between 0.2 μm and 1.5 μm. Here, the second branch has a horizontal width equal to 200 nm. The isolating regions 108 and 117 have a vertical height of less than 600 nm, here equal to 100 nm.

The main portions of the first and second vertical gates 111, 112 are facing each other in the plane of the upper face 100.1, preferably, as is the case here, the main portions are parallel to each other. Here, when viewed from above, they are substantially rectilinear and facing each other along their entire length.

In this example, so as to simplify the pixel design, the first and second sense nodes 121, 122 are symmetrical to each other relative to the axis of symmetry, without this being an essential feature of the invention. Thus, only the second sense node 122 is described in detail hereinafter, in relation to FIGS. 1A and 1C. The constituent elements of the first sense node 121 are deduced by the axial symmetry of symmetrical constituent elements of the second sense node 122. A feature or parameter defined for the second sense node 122 relative to the second vertical gate 112 is transposed to the first sense node 121 relative to the first vertical gate 111 by applying axial symmetry.

The second sense node 122 comprises an N-doped region 151 and an optional N-heavily doped region 152. The N-heavily doped region 152 comprises a strictly greater concentration of donor-type dopant elements than a concentration of donor-type dopant elements of the N-doped region 151. Preferably, the N-heavily doped region 152 makes it possible to produce an ohmic contact between the second sense node 122 and the readout circuit.

The N-doped region 151 is interposed between the peripheral isolation trench 105 and the second vertical gate 112. It extends vertically in the substrate 100 from the upper face 100.1, to a depth greater than the height of the isolating region 117. In this example, it is laterally delimited by the second vertical gate 112, so as to be surrounded by the second vertical gate 112 on three of its sides when viewed from above. The N-doped region 151 extends horizontally over a length L_{N}, from the first branch to the second branch of the second vertical gate 112. Viewed from above, it extends over a width W_{N}, up to the main portion of the second vertical gate 112. In this example, the first and second branches of the first and second vertical gates 111, 112 are of equal lengths. The N-doped region 151 has a width Wn, measured parallel to the axis X, substantially equal to the length measured parallel to the axis X of the first and second branches of the second vertical gate 112.

Each N-heavily doped region 152 is formed within an N-doped region 151. It extends from the upper face 100.1 to a depth less than the N-doped region 151. Here, all of its horizontal dimensions are strictly less than corresponding horizontal dimensions of the N-doped region 151.

In this example, the N-doped region 151 has a concentration of donor-type dopant elements of between 1E16 at/cm³ and 5E20 at/cm³. The N-heavily doped region 152 has a concentration of donor-type dopant elements of between 1E17 at/cm³ and 5E20 at/cm³. The N-doped region 151 has a height measured along the axis Z that exceeds the height of the isolating region 117 from 0 nm to 400 nm. The N-superdoped region 152 has a height measured along the axis Z between 10 nm and 200 nm. The width Wn is between 10% and 40% of the pixel size Pₓ, here equal to 326 nm.

The P-well 141 is doped with acceptor-type dopant elements. Viewed from above, the P-well 141 preferably surrounds the first and second vertical gates 111, 112, the first and second sense nodes 121, 122. Here, it also surrounds the collection zone 130. In this embodiment, it has a closed contour molding the peripheral isolation trench 105, viewed from above. It extends vertically in the substrate 100 from the upper face 100.1, over a depth greater than the height of the isolating region 108 of the peripheral isolation trench 105. It extends here along the axis Z over a depth greater than the height of the N-doped region 151, i.e. over a depth greater than the heights of the first and second sense nodes 121, 122.

The P-well 141 is in contact with the inner wall of the peripheral isolation trench 105, thus forming a reserve of holes drifting along the inner wall of the peripheral isolation trench 105, particularly when the peripheral isolation trench 105 is biased in strong inversion. For this particular pixel, a negative potential is applied to the vertical electrode 106 when the sensor is in operation, so as to attract holes of the P-well 141 along the inner wall. The holes participate in the passivation of the interface of the substrate 100 with the inner wall, and in the formation of a potential barrier. Preferably, as shown here, the P-well 141 is in contact with the inner wall of the peripheral isolation trench 105 on substantially all of its perimeter, viewed from above.

For example, the P-well 141 has a concentration of acceptor-type dopant elements of between 1E16 at/cm³ and 1E19 at/cm³. It has a height measured parallel to the axis Z that exceeds the height of the isolating region 108 from 0 nm to 400 nm.

The collection zone 130 comprises an N-doped region 143. It comprises, as shown here, an optional N-heavily doped region 144 and an optional N-well 142. The N-doped region 143 extends horizontally from the main portion of the first vertical gate 111 to the main portion of the second vertical gate 112. The collection zone 130 extends vertically in the substrate 100 from the upper face 100.1 over a depth greater than the height of the isolating regions 117 of the first and second vertical gates 111, 112. The N-heavily doped region 144 is formed within the N-doped region 143. It has a greater concentration of donor-type dopant elements than a concentration of donor-type dopant elements of the N-doped region 143. Preferably, the N-superdoped region 144 makes it possible to produce an ohmic contact between the collection zone 130 and the readout circuit.

The N-well 142 extends horizontally from the main portion of the first vertical gate 111 to the main portion of the second vertical gate 112. It extends vertically in the substrate 100 to a greater depth than the N-heavily doped region 144 and the N-doped region 143. Viewed from above, the N-doped region 143 occupies for example a pixel surface area located within the N-well 142. Here, the N-well 142 extends along the axis Y, between the main portions of the first and second vertical gates 111, 112, over a length strictly less than an opposite length, along which the first and second vertical gates 111, 112 are facing each other when viewed from above. Thus, the collection zone 130 extends along the axis Y over a length L_{C} strictly less than the opposite length. In FIG. 1A, it is centered on the center of the pixel.

Advantageously, the N-doped region 143 (respectively the N-heavily doped region 144) of the collection zone 130 and the N-doped regions 151 (respectively the N-heavily doped regions 152) of the first and second sense nodes 121, 122 are produced with the same method steps, such that they have substantially equal depths and substantially equal doping profiles in Z. A concentration of donor-type dopant elements of the N-well 142 and/or its depth are chosen to increase a proportion of electrical charges transferred by the collection channel and/or the first channel and/or the second channel during one or more phases of operation of the depth image sensor. In this embodiment, the N-well 142 extends vertically in the substrate 100 to a greater depth than the first and second sense nodes 121, 122 to promote the transfer of electrical charges from the photosensitive region 120 to the collection zone 130, during an initialization phase of the photosensitive region 120 and/or a readout phase of samples collected on the first and second sense nodes 121, 122, when the sensor is in operation.

The length L_{C} is for example greater than or equal to 100 nm. The length L_{N} can be between 15% and 60% of the pixel size Pₓ, here equal to 584 nm. The N-doped region 143 has a concentration of donor-type dopant elements of between 1E16 at/cm³ and 5E20 at/cm³. The N-superdoped region 144 has a concentration of donor-type dopant elements of between 1E17 at/cm³ and 5E20 at/cm³. The N-well 142 has a concentration of donor-type dopant elements of between 1E16 at/cm3 and 1E19 at/cm3.

The photosensitive region 120 is a region of the substrate 100 intended to collect photons and convert them into electrical charges. It occupies an N-doped region of the substrate 100, having a concentration of donor-type dopant species of between 1E12 at/cm³ and 1E18 at/cm³. In this example, the photosensitive region 120 is intended to receive the photons from the lower face of the substrate 100. The lower face can be coated with a passivation layer, for example a P-doped silicon layer.

The first and second sense nodes 121, 122 and the collection zone 130 are vertically aligned with the photosensitive region 120. The first channel (respectively second channel) is a region of the substrate 100 occupied by photogenerated electrical charges in the photosensitive region 120 during their transit from the photosensitive region 120 to the first (respectively second) sense node 121 (respectively 122) when the sensor is in operation. Similarly, the collection channel is a region of the substrate 100 occupied by photogenerated electrical charges in the photosensitive region 120 during their transit from the photosensitive region 120 to the collection zone 130 when the sensor is in operation.

The first and second channels, and the collection channel are located in the substrate 100 between the photosensitive region 120 and, respectively, the first sense node 121, the second sense node 122 and the collection zone 130. The first channel is located at least partially between the first branch, the second branch and the main portion of the first vertical gate 111. The second channel is located at least partially between the first branch, the second branch and the main portion of the second vertical gate 112. The collection channel is located at least partially between the main portions of the first and second vertical gates 111, 112.

The U-shape of the first (respectively second) vertical gate 111 (respectively 112) makes it possible to improve the control of the first (respectively second) channel. It particularly makes it possible to increase the proportion of electrical charges transferred from the photosensitive region 120 to the first sense node 121 (respectively second sense node 122) when the first channel (respectively second channel) is on and the second channel (respectively first channel) is off.

Viewed from above, the main portions of the first and second vertical gates 111, 112 are spaced apart by a distance S, at the collection zone 130 and the collection channel.

The first channel, the second channel and the collection channel are here doped with the same type as the first and second sense nodes 121, 122 and with the same type as the collection zone 130, i.e. N-type. They each have a concentration of dopant species which is strictly less than respective minimum concentrations of the first and second sense nodes 121, 122 and of the collection zone 130. Here, they have substantially the same concentration of dopant atoms. For example, they have a concentration of dopant atoms of between 1E12 at/cm³ and 1E18 at/cm³.

The readout circuit is shown schematically in FIG. 3A. It comprises the first gate contact 161, a second gate contact 162, an initialization contact 163, a P-contact 164, a peripheral contact 165, a first contact 166 and a second contact 167, as shown in FIG. 1A. Each of these contacts is preferably metallic.

The first and second gate contacts 161, 162 make it possible to apply respectively a first electrical signal TGZ1 to the first vertical gate 111 and a second electrical signal TGZ2 to the second vertical gate 112. They are in physical contact with the gate electrode 115 of the first vertical gate 111 and the second vertical gate 112, respectively. They pass through either side of the isolating regions 117 of each vertical gate 111, 112. The electrical signals TGZ1, TGZ2 are variable electrical potentials over time.

The initialization contact 163 makes it possible to apply an electrical potential VRT to the collection zone 130. It is in physical contact with the N-heavily doped region 144 of the collection zone 130. In this embodiment, it is located at the center of the pixel, between the main portions of the first and second vertical gates 111, 112. For better control of the collection channel, the distance S is preferably chosen equal to a minimum distance allowed by design rules of the technology used to produce the sensor. Design rules generally take into account a minimum distance allowed between an electrical contact and a vertical gate, and a minimum dimension for an electrical contact. By way of example, the distance S is between 10 nm and 300 nm, here equal to 108 nm.

The first and second contacts 166, 167 are in physical contact with the N-heavily doped region 152 of the first sense node 121 and the second sense node 122, respectively. In operation, their electrical potentials are respectively equal to values V_{ech1} and V_{ech2}.

The P-contact 164 makes it possible to apply an electrical potential V_{P} to the P-well 141. It is in physical contact with the P-well 141 at a peripheral region of the pixel, preferably maximizing a distance separating the contact P 164 from the first and second vertical gates 111, 112 and the peripheral isolation trench 105. Here, it is located in the plane parallel to the plane (Y, Z) passing through the center of the pixel.

The peripheral contact 165 makes it possible to apply an electrical potential V_{CDTI} to the peripheral isolation trench 105. It is in physical contact with the vertical electrode 106 and passes through either side of the isolating region 108 of the peripheral isolation trench 105.

The photosensitive region 120 is electrically connected to the first sense node 121 and to the second sense node 122 via the first transfer transistor 51.1 and the second transfer transistor 51.2, respectively. It is electrically connected via the P-well 141 and the P-contact 164 to a node or a rail for supplying an electrical potential V_{P}.

The readout circuit comprises blocks for reading a sample. In this example, the number of readout blocks is equal to the number of samples collected by the pixel. Here, they are identical and two in number. Each is electrically connected to a sense node 121, 122 and to an output rail Vx1, Vx2 of the readout circuit. Each readout block comprises a precharge transistor 52, a transistor 53 mounted in a source follower and a selection transistor 54.

The drains of the first and second transfer transistors 51.1, 51.2 are respectively electrically connected to the gate of the transistor 53 and to the source of the precharge transistor 52 of a separate readout block. The transistor source 53 is connected to the drain of the selection transistor 54. The drain of the transistor 53 is connected to a node or a rail for supplying an electrical potential VSF. The drain of the precharge transistor 52 is connected to a node or a rail for supplying an electrical potential V_{RST}. The source of the selection transistor 54 is connected to the output rail Vx1, if the readout block is connected to the first sense node 121, otherwise to the output rail Vx2. The precharge transistors 52 make it possible to initialize the first and second sense nodes 121, 122 at an electrical potential substantially equal to V_{RST}.

The initialization contact 163 is electrically connected to a node or a rail for supplying an electrical potential VRT. It is electrically connected to the photosensitive region 120 via the initialization transistor 50. In the first embodiment, the initialization transistor 50 is a double gate type transistor, the gate(s) of which are the first and second vertical gates 111, 112.

The first vertical gate 111 is electrically connected to a node or a rail for supplying a first electrical signal TGZ1. The second vertical gate 112 is electrically connected to a node or a rail for supplying a second electrical signal TGZ2. The first and second electrical signals TGZ1, TGZ2 are variable electrical potentials over time.

A variant of the first embodiment will now be described in relation to FIGS. 2A, 2B and 2C. FIG. 2A is a schematic top view. FIG. 2A shows the sectional plane A-A of FIG. 2B, and the sectional plane B-B of FIG. 2C. FIGS. 2B and 2C represent mappings of the concentration of dopant elements in these sectional planes, obtained by simulation. Only the differences with the first embodiment are described below.

In this variant, the pixel further comprises a peripheral contact zone 130.1 on which the initialization contact 163 rests. The peripheral contact zone 130.1 is in physical and electrical contact with the collection zone 130. For example, it is formed of one piece with the collection zone 130. It is doped with the same conductivity type as the collection zone 130, here N-type. It extends in depth in the substrate 100 from the upper face 100.1. In this example, it extends horizontally from the collection zone 130 and from the first and second vertical gates 111, 112, up to the peripheral isolation trench 105. For example, it has a height along the axis Z, less than or equal to the height of the collection zone 130, without this being essential.

The peripheral contact zone 130.1 has dimensions and a concentration of dopant elements that are adjusted so as not to create a potential barrier or well between the collection zone 130 and the initialization contact 163 when the sensor is in operation. When the peripheral contact zone 130.1 and the collection zone 130 are of equal heights, they can be produced with the same series of method steps. They then have substantially identical doping profiles along the Z axis, as is the case in FIG. 2C.

Viewed from above, the initialization contact 163 is offset in a peripheral region of the pixel making it possible to move the first and second vertical gates 111, 112 closer, without infringing upon a design rule of the technology used to produce the sensor, such as a minimum spacing rule between a contact and a vertical gate. The distance S can thus be reduced relative to the first embodiment. It is here equal to 70 nm. Moving the first and second vertical gates 111, 112 closer makes it possible to favor the transfer of photogenerated charges from the photosensitive region 120 to the first and second sense nodes 121, 122 relative to the transfer to the collection zone 130.

In this variant, the contour of the P-well 141 molds that of the peripheral isolation trench 105 when viewed from above, except for a region of the pixel within which the peripheral contact zone 130.1 is in contact with the peripheral isolation trench 105.

FIG. 3B shows a timing diagram illustrating a possible operation of the readout circuit of the first embodiment or the variant of the first embodiment. It is assumed here that the plurality of pixels is arranged in an array.

When a scene is illuminated by a periodic light source in amplitude of period P_{S}, the timing diagram results in an integration by each sense node 121, 122 of respective and distinct parts of the light signal reflected by the scene. Each sense node 121, 122 integrates the light signal reflected over periodic time intervals of period equal to the period P_{S} and of duration equal to P_{S}/4. The time intervals of the second sense node 122 are spaced apart from the time intervals of the first sense node 121 by a duration equal to P_{S}/4.

The timing diagram comprises a sampling phase T2 immediately followed by an array read phase T3. The sampling phase T2 is preceded by an initialization phase T1. Combining the consecutive phases T1 to T3 constitutes a phase of a depth image acquisition, or a frame acquisition, for example if the sensor is capable of capturing several successive images. Where applicable, the array readout phase T3 of one frame can be immediately followed by the initialization phase T1 of the next frame, as shown here. The array readout phase T3 comprises a line readout phase T3.1 of the array to which the pixel belongs.

In order to determine depth information from the periodic light signal received by the sensor, the pixel can be associated with another identical pixel for which the timing diagram has its sampling phase T2 offset by a quarter of the period P_{S}, modulo the period P_{S}. Alternatively, the sampling phases T2 of two successive frames can be offset by a quarter of the period P_{S} modulo the period P_{S}, and the depth information is determined from the samples collected by the pixel during the acquisition phases of the two successive frames.

During the sampling phase T2, the photogenerated charges are transferred in the photosensitive region 120, alternately to the first and second sense nodes 121, 122. For this purpose, the first and second transfer transistors 51.1, 51.2 are alternately set to the on state over periodic time intervals of a period equal to the period P_{S}, each time interval being equal to P_{S}/4. During the sampling phase T2, the first electrical signal TGZ1 and the second electrical signal TGZ2 switch in opposite phase, between a first value V₁ and a second value V₂, via a third value V₃ for a duration equal to P_{S}/4.

When the electrical potentials applied to the first and second vertical gates 111, 112 are respectively equal to V₁ and V₂, the second transfer transistor 51.2 is in an on state, whereas the first transfer transistor 51.1 and the initialization transistor 50 are in off states. Conversely, when the electrical potentials applied to the first and second vertical gates 111, 112 are respectively equal to V₂ and V₁, the first transfer transistor 51.1 is in an on state, whereas the second transfer transistor 51.2 and the initialization transistor 50 are in off states.

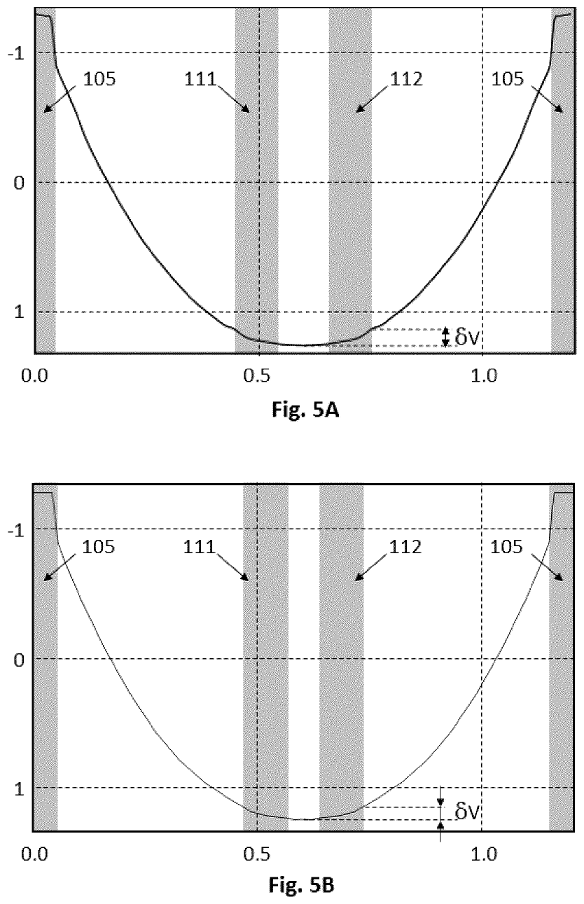

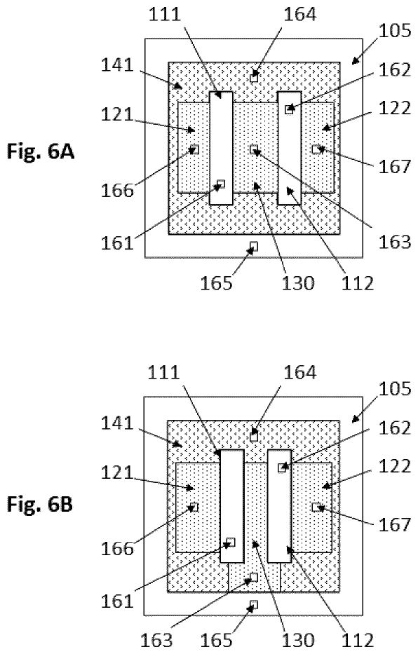

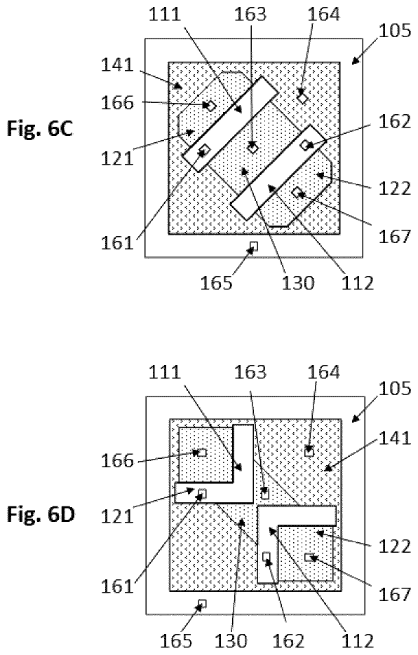

In this example for which the transferred charges are electrons, V₁ is equal to −0.8 V and V₂ is equal to 1.8 V. Under these conditions, a mapping of the simulated electrical potential is given in FIG. 4B. FIG. 4B shows a time of the sampling phase T2 for which the second transfer transistor 51.2 is in an on state, while the first transfer transistor 51.1 and the initialization transistor 50 are in off states.

At the top left of FIGS. 4A to 4C, a mapping of the electrical potential of the first embodiment is given, in the sectional plane A-A of FIG. 1A. At the bottom left of FIGS. 4A to 4C, a mapping of the electrical potential of the variant of the first embodiment is given, in the sectional plane A-A of FIG. 2A. At the bottom right of FIGS. 4A to 4C, a mapping of the electrical potential of the variant of the first embodiment is given, in the sectional plane B-B of FIG. 2A. The three mappings of the same figure are obtained for the same electrical bias state of the pixel. At the top right, the equivalence in Volts of the grayscales used on the mappings is given. In these figures, the approximate positions of certain potential barriers are represented by double lines. A general direction of each priority transfer of photogenerated charges in the photosensitive region 120 has also been represented by a dashed arrow.

FIG. 4C shows a time of the array readout phase T3 or a time of an initialization phase of the photosensitive region 120 similar to the initialization phase T1 for which the first and second vertical gates 111, 112 are biased at a lower electrical potential. FIG. 4A shows a bias state of the pixel that can be used in a possible alternative timing diagram.

The simulation results of FIGS. 4A to 4C are obtained by setting VRT to 1.8 V, V_{RST} to 1.8 V, V_{CDTI} to −0.8 V and V_{P} to −0.5 V. For these simulations, the first and second contacts 166, 167 are at an electrical potential of 1.8 V, which is their electrical initialization potential, i.e. before collecting electrical charges. The electrical potential of the initialization contact 163 is equal to 1.8 V.

In FIG. 4B, the gradient of the electrical potential reaches a maximum in absolute values in a direction (dashed white arrow) connecting the photosensitive region 120 to the second sense node 122, such that 99% of the charges transferred from the photosensitive region 120 reach the second sense node 122. Thus, the second channel is on independently of the first channel and the collection channel.

During the array readout phase T3, the first and second vertical gates 111, 112 are simultaneously biased at an electrical bias voltage greater than or equal to a threshold voltage of the first and second transfer transistors 51.1, 51.2. However, the particular arrangement of the first and second vertical gates 111, 112, relative to one another, keeps the first and second transfer transistors 51.1, 51.2 in an off state.

During this phase, the first and second vertical gates 111, 112 are kept at an electrical potential equal to an intermediate value Vᵢ, making it possible to prevent a charge transfer from the photosensitive region 120 to a sense node 121.122. Preferably, the first and second vertical gates 111, 112 are kept at the electrical potential Vᵢ throughout the array readout phase T3, as shown here. The electrical potential Vᵢ turns on the initialization transistor 50.

According to a first option, applying the electrical potential Vᵢ lowers a potential barrier located between the collection zone 130 and the photosensitive region 120 so that it is lower than potential barriers located between, on one hand, the photosensitive region 120, and, on the other hand, the first and second sense nodes 121, 122.

According to a second option obtained in FIG. 4C, the electrical potential Vᵢ applied to the first and second vertical gates 111, 112 is sufficient to create an electrical field tending to converge as a priority the photogenerated charges toward the collection channel. The electrical potential gradient being maximum in the direction of the collection zone 130, there is an electrical potential difference δV between a face of each vertical gate 111, 112 facing a sense node 121, 122 and an opposite face of the same vertical gate facing the collection zone 130.

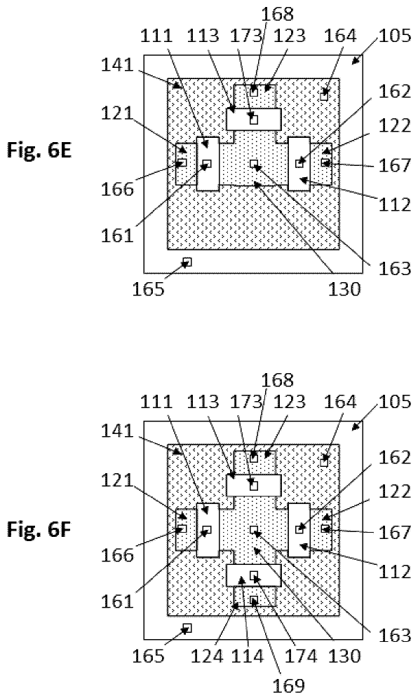

In FIGS. 5A and 5B, the value of the electrical potential of FIG. 4C has been shown, along horizontal segments [X′o, Xo] intersecting a central axis of the pixel and a lower face of each vertical gate 111.112 (represented by dash-dotted lines in FIG. 4C). In these figures, the electrical potential is given in Volts on the y-axis. On the x-axis, the position in the pixel along [X′o, Xo] is given in μm. The positions of the peripheral isolation trench 105 and of the first and second vertical gates 111, 112 are represented in gray. FIG. 5A corresponds to the first embodiment, FIG. 5B to the variant of the first embodiment. The potential difference δV is identified in these figures. It is equal to 126 mV for FIGS. 5A and 111 mV for FIG. 5B. These values are sufficient for at least 97% of the charges transferred from the photosensitive region 120 to reach the collection zone 130.

Thus, during the array readout phase T3, the initialization transistor 50 has an anti-blooming function for the first and second sense nodes 121, 122, and the reading of the electrical potentials of the first and second sense nodes 121, 122 is not distorted during the array readout phase T3.

The intermediate value Vᵢ is for example greater than or equal to V₂. In this example, Vᵢ is equal to V₂.

At a time of the array readout phase T3, the line readout phase T3.1 starts when the selection transistor 54 is set to an on state (RD has a high value). A first readout of the first and second sense nodes 121, 122 is performed at a time t_{S} of the line readout phase T3.1 corresponding to a collection of samples. Subsequently, a voltage pulse is applied to the gate of the precharge transistors 52 to initialize the first and second sense nodes 121, 122 at an electrical potential V_{ech1}, V_{ech2} substantially equal to VRST. Then, a readout of a reference potential of each sense node 121, 122 is read at a time t_{R} of the line readout phase T3.1.

During the initialization phase T1, the first and second vertical gates 111, 112 are simultaneously biased at an electrical potential equal to the third value V₃, greater than or equal to V₂ and to Vᵢ. During this phase, the collection channel is on independently of the first channel and the second channel. The photosensitive region 120 is therefore voided of the electrical charges contained therein. The photosensitive region 120 is thus initialized, or reset. In the timing diagram, V₃ is strictly greater than V₂ and equal to 2.5 V. Similarly, the photosensitive region 120 is initialized during the sampling phase T2 between each switching of the first and second electrical signals TGZ1, TGZ2.

In FIG. 4A, a scenario for which TGZ1 and TGZ2 are equal to −0.8 V has been shown, making it possible to create a potential barrier between, on one side, the photosensitive region 120 and, on the other, the first and second sense nodes 121, 122 and the collection zone 130. In this case, no photogenerated charges in the photosensitive region 120 are transferred to a sense node 121, 122 or to the collection zone 130.

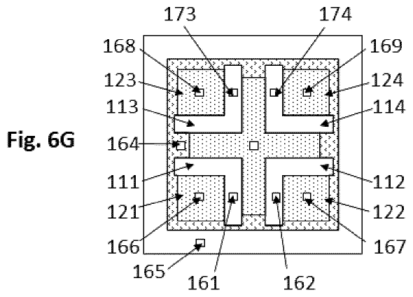

Further embodiments of the invention are now described. Only the differences with the first embodiment are explained. For some embodiments, the first and second vertical gates 111, 112 can have other shapes when viewed from above, such as for example an I-shape with or without a serif at the top and/or at the bottom of the I. In FIGS. 6A to 6C, examples of pixels comprising first and second rod-shaped vertical gates 111, 112 (“I” without a serif) have been shown viewed from above.

In FIG. 6A, the initialization contact 163 is positioned at the center of the pixel, similarly to the first embodiment. In FIG. 6B, the initialization contact 163 is positioned at the periphery of the pixel, similarly to the variant of the first embodiment. FIG. 6C shows a similar scenario to that of FIG. 6A, for which the first and second vertical gates 111, 112 have been rotated by 45° about an axis parallel to the axis Z passing through the center of the pixel.

The first and second vertical gates 111, 112 may only have one branch among the first and second branches. They then have a general L-shape, viewed from above. Such an example is illustrated in FIG. 6D. Therein, the main portions of the first and second vertical gates 111, 112 are not facing each other, but it may be advantageous for that to be the case. The initialization contact 163 can occupy any position of the pixel, offset or not. The first and second vertical gates 111, 112 can form any angle with the axes X or Y in a plane parallel to the plane (X, Y).

According to one benefit of the invention, the surface area of the pixel designated for the initialization of the photosensitive region 120 is reduced relative to embodiments of the prior art. This advantage can be utilized to increase the number of transfer gates per pixel, without increasing the size of the pixel Px. Thus, it is possible to increase the number of samples collected per pixel. FIGS. 6E to 6G illustrate embodiments of the invention having a number of transfer transistors strictly greater than 2, each comprising a distinct vertical transfer gate, a distinct channel controllable by the vertical gate, and a distinct sense node. All of the sense nodes and the collection zone 130 are doped with the same conductivity type.

In these embodiments, the initialization transistor 50 has as many gates as there are transfer gates in the pixel. Each gate of the initialization transistor 50 is a pixel transfer gate for collecting a sample. In operation, the charges transferred from the photosensitive region 120 transit in priority to the collection zone 130 when all the transfer gates are biased at the potential V₃. When all the transfer gates are biased at the potential Vᵢ, the initialization transistor 50 ensures an anti-blooming function during an array readout phase T3. The readout circuit is configured to apply one electrical signal per transfer gate so as to alternately turn on a single channel among all of the channels associated with a transfer gate and the collection channel 130 and to transfer photogenerated electrical charges via this channel in priority.

In FIG. 6E, an embodiment having three transfer gates for collecting three samples has been illustrated. It has a similar configuration to that of FIG. 6A, for which a third rod-shaped vertical gate 113 and a third sense node 123 have been added. The third vertical gate 113 is identical to the first and second vertical gates 111, 112. The third sense node 123 is identical to the first and second sense nodes 121, 122.

Viewed from above, the first, second and third vertical gates 111, 112, 113 are centered on 3 consecutive sides of an imaginary square, itself centered on the pixel. The readout circuit further comprises a third gate contact 173 in physical contact with the gate electrode 115 of the third vertical gate 113, and a third contact 168 in physical contact with the third sense node 123.

In an alternative embodiment, the three vertical gates can be rotated together by 45°. The initialization contact 163 can be offset at the periphery of the pixel.

FIG. 6F shows an embodiment having four vertical transfer gates for collecting four samples. It has a similar configuration to that of FIG. 6E, for which a fourth rod-shaped vertical gate 114 and a fourth sense node 124 have been added. The fourth vertical gate 114 is identical to the other vertical gates. The fourth sense node 124 is identical to the other sense nodes.

Viewed from above, the four vertical gates are centered on four sides of an imaginary square centered on the pixel. The readout circuit further comprises a fourth gate contact 174 in physical contact with the gate electrode 115 of the fourth vertical gate 114, and a fourth contact 169 in physical contact with the fourth sense node 124.

FIG. 6G shows another embodiment comprising four vertical transfer gates. Therein, the vertical gates each have an L-shape when viewed from above.

Particular embodiments have just been described. Different variants and modifications will become apparent to the person skilled in the art.

1. A depth image sensor comprising a readout circuit and a plurality of pixels formed in and on a substrate (100) of the sensor, each pixel comprising:
a photosensitive region (120) formed in the substrate (100) and configured to convert photons into electrical charges,
a first sense node (121), a second sense node (122) and a collection zone (130) vertically aligned with the photosensitive region (120) and doped with a first conductivity type,
a first transfer transistor (51.1) comprising a first vertical gate (111) and a first channel controllable by the first vertical gate (111),
a second transfer transistor (51.2) comprising a second vertical gate (112) and a second channel controllable by the second vertical gate (112),
a multi-gate initialization transistor (50) of the photosensitive region, comprising the first and second vertical gates (111, 112) and a collection channel controllable by the first and second vertical gates (111, 112),
the pixel being such that the first channel, the second channel and the collection channel extend in the substrate (100) between the photosensitive region (120) and, respectively, the first sense node (121), the second sense node (122) and the collection zone (130);
the readout circuit being configured to apply a first electrical signal (TGZ1) to the first vertical gate (111) and a second electrical signal (TGZ2) to the second vertical gate (112) so as to alternately turn on each of the first channel, the second channel and the collection channel, independently of the two other channels.

2. The sensor according to claim 1, wherein the collection zone (130) extends vertically in the substrate (100) to a greater depth than the first and second sense nodes (121, 122).

3. The sensor according to claim 1, wherein each pixel further comprises a peripheral isolation trench (105) extending vertically in the substrate (100) from an upper face (100.1) of the substrate (100) and laterally delimiting the photosensitive region (120).

4. The sensor according to claim 3 further comprising a doped well (141) of a second conductivity type opposite the first conductivity type, wherein the well (141) is in contact with the peripheral isolation trench (105) and flush with the upper face (100.1) of the substrate (100).

5. The sensor according to claim 4, wherein the peripheral isolation trench (105) comprises a vertical electrode (106) made of a doped semiconductor material of the second conductivity type.

6. The sensor according to claim 1, wherein the first and second vertical gates (111, 112) comprise respective main portions facing each other, symmetrical to each other relative to a vertical axis of symmetry passing through the center of the pixel and wherein the collection zone (130) extends from one main portion to the other.

7. The sensor according to claim 6, wherein the first and second vertical gates (111, 112) each have a U-shape when viewed from above, and wherein the first sense node (121) and the second sense node (122) each extend between two opposite branches of the U formed by, respectively, the first vertical gate (111) and the second vertical gate (112).

8. The sensor according to claim 6, wherein the readout circuit comprises an initialization contact (163) and the pixel further comprises a peripheral contact zone (130.1) of the first conductivity type, extending the collection area (130) in a peripheral region of the pixel on which the initialization contact (163) rests.

9. The sensor according to claim 1, wherein the readout circuit is configured to switch in opposite phase, the first electrical signal (TGZ1) and the second electrical signal (TGZ2) between a first value and a second value so as to alternately turn on the first channel and the second channel during a sampling phase (T2), while keeping the collection channel off.

10. The sensor according to claim 9, wherein the readout circuit is configured to assign a third value to the first electrical signal (TGZ1) and the second electrical signal (TGZ2) so as to turn on the collection channel during an initialization phase (T1) of the photosensitive region (120) preceding the sampling phase (T2).

11. The sensor according to claim 10, wherein the plurality of pixels are arranged in an array, and wherein the readout circuit is configured to assign an electrical potential equal to an intermediate value to the first and second vertical gates (111, 112) so as to prevent a transfer of photogenerated electrical charges in the photosensitive region (120) to the first and second sense nodes (121, 122) during an array readout phase (T3), the intermediate value being different from the third value.
